(19) United States
(12) Patent Application Publication
(10) Pub. No.: US 2016/0133738 A1
(43) Pub. Date: May 12, 2016

(54) HIGH ELECTRON MOBILITY TRANSISTOR AND MANUFACTURING METHOD THEREOF

(71) Applicant: National Chiao Tung University, Hsinchu City (TW)

(72) Inventors: Edward Yi CHANG, Hsinchu County (TW); Yueh-Chin LIN, New Taipei City (TW); Ting-En HSIEH, Tainan City (TW)

(21) Appl. No.: 14/597,012

(22) Filed: Jan. 14, 2015

(30) Foreign Application Priority Data
Nov. 6, 2014 (TW) 103138491

(51) Int. Cl. H01L 29/778; H01L 29/201; H01L 21/02; H01L 29/66; H01L 29/423; H01L 29/20; H01L 29/205

(52) U.S. Cl. CPC H01L 29/7787; H01L 29/2003; H01L 29/201; H01L 29/205; H01L 29/7786; H01L 29/66462; H01L 29/4236; H01L 21/02458; H01L 21/02164; H01L 21/02178; H01L 21/02112; H01L 21/0254; H01L 21/02543; H01L 21/02546

(57) ABSTRACT

A high electron mobility transistor is realized in the present invention by a gate recessed structure, a high permittivity oxide layer and a nitride-based interfacial passivation layer, featuring high threshold voltage, high transconductance, highly stable drain output current, and high reliability.

### BACKGROUND OF THE INVENTION

1. Field of the Invention

The present invention relates to a transistor and a manufacturing method thereof, particularly to a high electron mobility transistor and a manufacturing method thereof.

2. Description of the Prior Art

As the gallium nitride high electron mobility transistor (GaN-HEMT) features high output power, high output voltage, and high temperature resistance, it has been extensively used in high power circuit systems. The conventional gallium nitride transistor has a great amount of polarization-induced charges functioning as two-dimensional electron gas (2DEG) in the GaN/GaAlN interface. This type of transistor is the so-called normally-on transistor. The normally-on transistor has a negative threshold voltage. While the gate voltage is zero, the normally-on transistor is still in a conduction state and suffers from unnecessary power consumption. The high power transistor operates in an extremely high voltage environment and is likely to experience voltage surges. If the threshold voltage is insufficient to resist the voltage surge, the high power transistor will be turned on abnormally, which may cause the circuit system to operate erroneously and affect stability of the system. Therefore, developing normally-off transistors is an important trend in the industry.

In the conventional GaN-HEMT technology, a high permittivity oxide layer is deposited in the transistor to realize normally-off GaN transistors with high threshold voltage and low gate leakage current. The high permittivity materials are normally metal oxides. While a metal oxide is deposited on the surface of the epitaxially-grown GaN, extra oxide is likely to form in the interface. Besides, the 2-dimensional electrons in the 2DEG channel are likely to be trapped by the gate oxide and thus cannot return to the 2DEG channel. Therefore, the conventional normally-off GaN transistor is likely to have the problem of threshold voltage hysteresis.

Accordingly, the related manufacturers and researchers are eager to improve the stability of the threshold voltage and the reliability of the transistor performance.

### SUMMARY OF THE INVENTION

The present invention provides a high electron mobility transistor with high threshold voltage and high reliability and a manufacturing method thereof.

One embodiment of the present invention proposes a high electron mobility transistor, which comprises a substrate, a channel layer, a donor supply layer, a source structure, a drain structure, an interfacial passivation layer, a dielectric layer, and a gate structure. The channel layer is formed on the substrate and includes a first group III-V compound. The donor supply layer is formed on the channel layer and includes a second group III-V compound, which is different from the first group III-V compound. The donor layer has a recess exposing a portion of the channel layer. The source structure and the drain structure are formed on the donor supply layer and respectively have ohmic contacts with the donor supply layer. The source structure and the drain structure are respectively disposed on the opposite sides of the recess. The interfacial passivation layer is formed on an inner surface of the recess. The dielectric layer is formed on the interfacial passivation layer. The gate structure is formed on the dielectric layer and corresponding to the recess.

Another embodiment of the present invention proposes a method for manufacturing a high electron mobility transistor, which comprises: forming a channel layer including a first group III-V compound on a substrate; forming a donor supply layer including a second group III-V compound on the channel layer; forming a source structure and a drain structure separated from each other and respectively having ohmic contacts with the donor supply layer on the donor supply layer; forming a recess exposing a portion of the channel layer and disposed between the source structure and the drain structure on the donor supply layer; forming an interfacial passivation layer on the inner surface of the recess; forming a dielectric layer on the interfacial passivation layer; and forming a gate structure on the dielectric layer and corresponding to the recess.

The present invention overcomes the problem of unstable threshold voltage caused by the high permittivity oxide layer disposed on a normally-off transistor, reducing standby power consumption and increasing the possibility of integrating normally-on and normally-off gallium nitride-based digital logic circuits.

Below, the embodiments are described in detail in cooperation with the attached drawings to make easily understood the objectives, technical contents, characteristics and accomplishments of the present invention.

### BRIEF DESCRIPTION OF THE DRAWINGS

FIG. 1 is a sectional view schematically showing a high electron mobility transistor according to one embodiment of the present invention;

FIGS. 2a-2d are sectional views schematically showing the steps of a method for manufacturing a high electron mobility transistor according to one embodiment of the present invention;

FIG. 3 is a sectional view schematically showing a high electron mobility transistor according to another embodiment of the present invention;

FIG. 4 shows the relationship of the drain current and the gate bias and the relationship of the transconductance and the gate bias according to one embodiment of the present invention;

FIG. 5a shows the relationship of the drain current and the gate bias of a control-group HEMT whose gate is free of the interfacial passivation layer.

FIG. 5b shows the relationship of the drain current and the drain bias of a control-group HEMT whose gate is free of the interfacial passivation layer;

FIG. 6a shows the relationship of the drain current and the gate bias of an HEMT according to one embodiment of the present invention; and

FIG. 6b shows the relationship of the drain current and the drain bias of an HEMT according to one embodiment of the present invention.

### DESCRIPTION OF THE PREFERRED EMBODIMENT

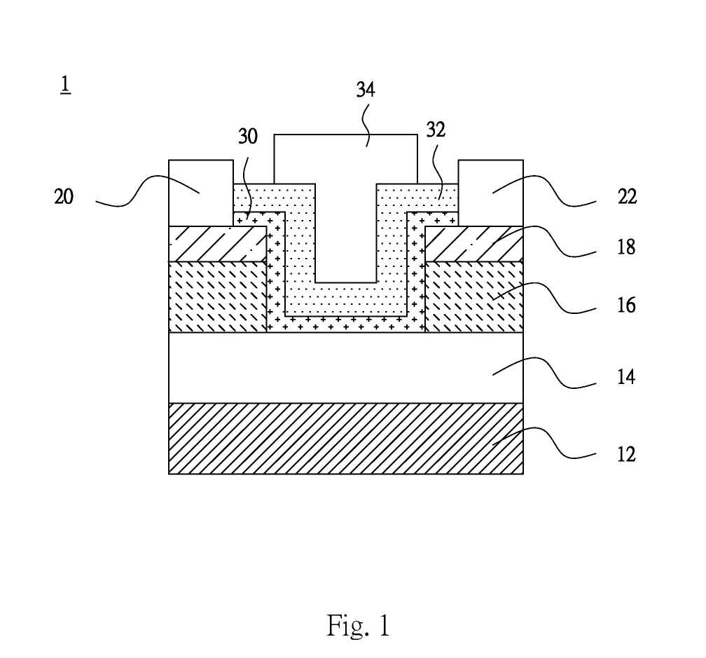

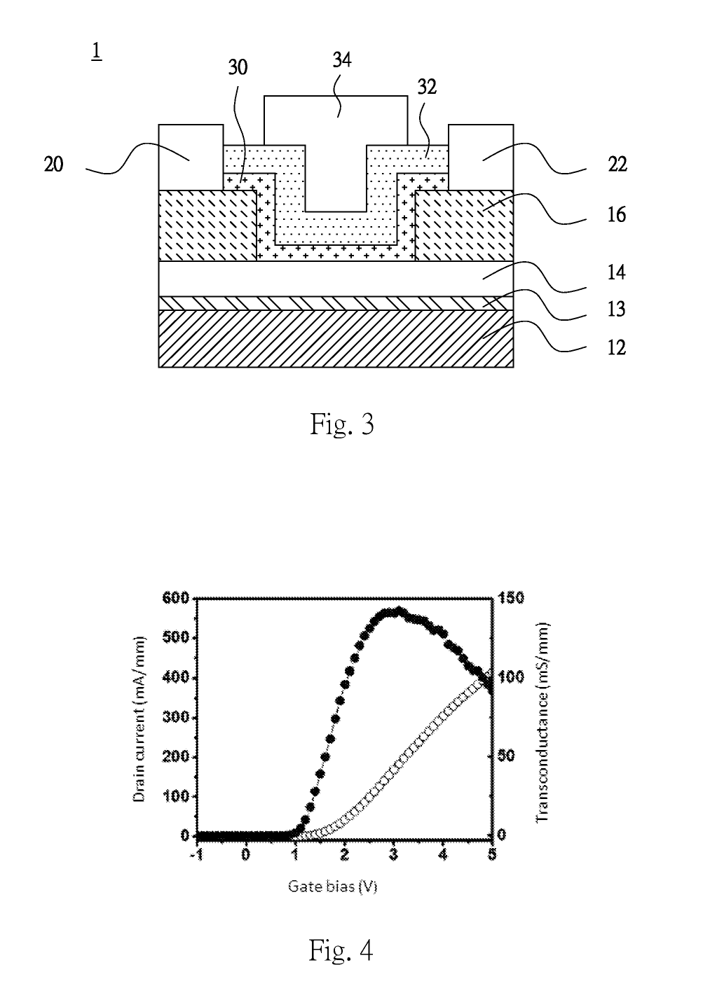

Refer to FIG. 1 a sectional view schematically showing a high electron mobility transistor according to one embodiment of the present invention. The high electron mobility transistor (HEMT) 1 of the present invention comprises a substrate 12, a channel layer 14, a donor supply layer 16, a protection layer 18, a source structure 20, a drain structure 22, an interfacial passivation layer 30, a dielectric layer 32, and a gate structure 34. In some embodiments, the substrate 12 is a silicon substrate, a silicon carbide substrate, or a sapphire substrate. Refer to FIG. 3. In some embodiments, a buffer layer 13 is formed on the substrate 12 to favor the succeeding epitaxial process. The buffer layer 13 is a technology well known for the persons skilled in the art. In some embodiments, the buffer layer 13 includes at least one of an aluminum nitride layer, a gallium aluminum nitride layer, and a gallium nitride layer.

The channel layer 14, the donor supply layer 16 and the protection layer 18 are formed over the substrate 12 in sequence. In some embodiments, the channel layer 14 is made of a first group III-V compound, such as gallium nitride, gallium arsenide, or indium phosphide. In some embodiments, the donor supply layer 16 is made of a second group III-V compound different from the first group III-V compound, such as gallium aluminum nitride, gallium aluminum arsenide, or indium aluminum phosphide. The donor supply layer 16 has a recess exposing a portion of the channel layer 14. Discrete energy bands respectively exist in the donor supply layer 16 and the channel layer 14. Owing to spontaneous polarization and piezoelectricity, a large amount of polarization-induced charges flow into the channel layer 14 to form a two-dimensional electron gas (2DEG) in the channel layer 14. The concentration of 2DEG below the recess of the supply donor layer 16 is too low to form a conduction path. Thus, the region below the recess is a carrier depletion zone. It means that the transistor is turned off under zero gate voltage. Therefore, HEMT 1 of the present invention is a normally-off transistor, exempted from standby power consumption.

Refer to FIG. 1 again. The source structure 20 and the drain structure 22 are formed on the protection layer 18 and have ohmic contacts with the protection layer 18. In some embodiments, the protection layer 18 is made of gallium nitride. The source structure 20 and the drain structure 22 are respectively disposed at the opposite sides of the recess. In some embodiments, the source structure 20 and the drain structure 22 are made of a Ti/Al/Ni/Au alloy and have ohmic contacts with the protection layer 18. In some embodiments, the protection layer 18 is omitted, and the source structure 20 and the drain structure 22 are directly formed on the donor supply layer 16. The interfacial passivation layer 30 is formed on an inner surface of the recess. The dielectric layer 32 is formed on the interfacial passivation layer 30. The gate structure 34 is formed on a region of the dielectric layer 32 and is corresponding to the recess. The dielectric layer 32 is made of a high permittivity oxide, such as silicon dioxide, nitrogen oxide (N₄O₃), or aluminum oxide (Al₂O₃). The gate structure 34 is made of at least one metallic material, such as a Ni/Au alloy.

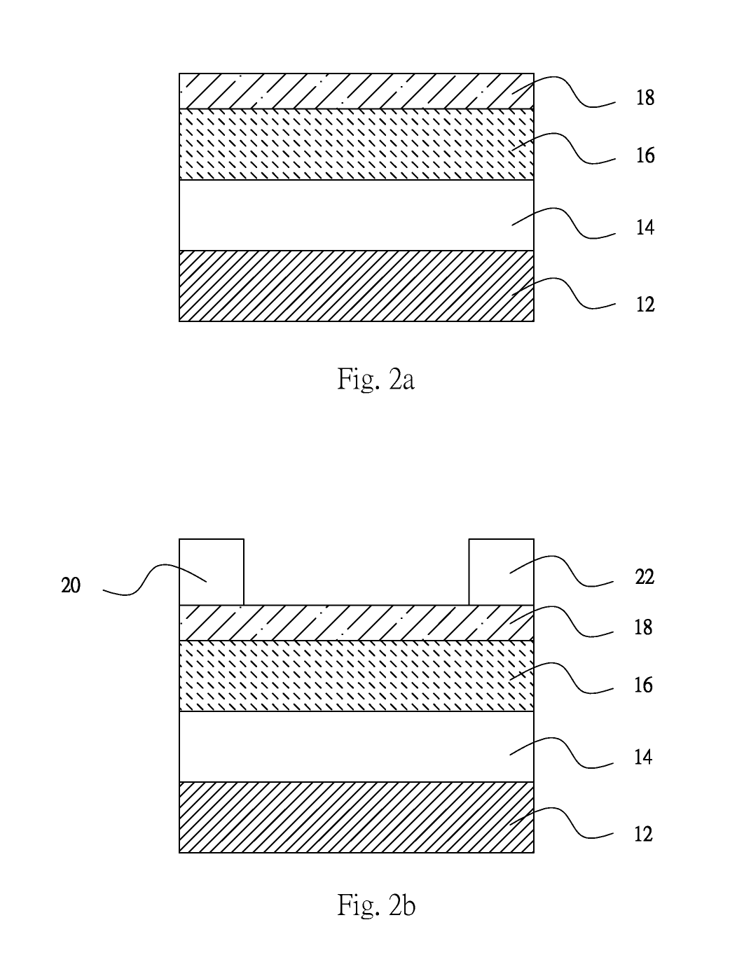

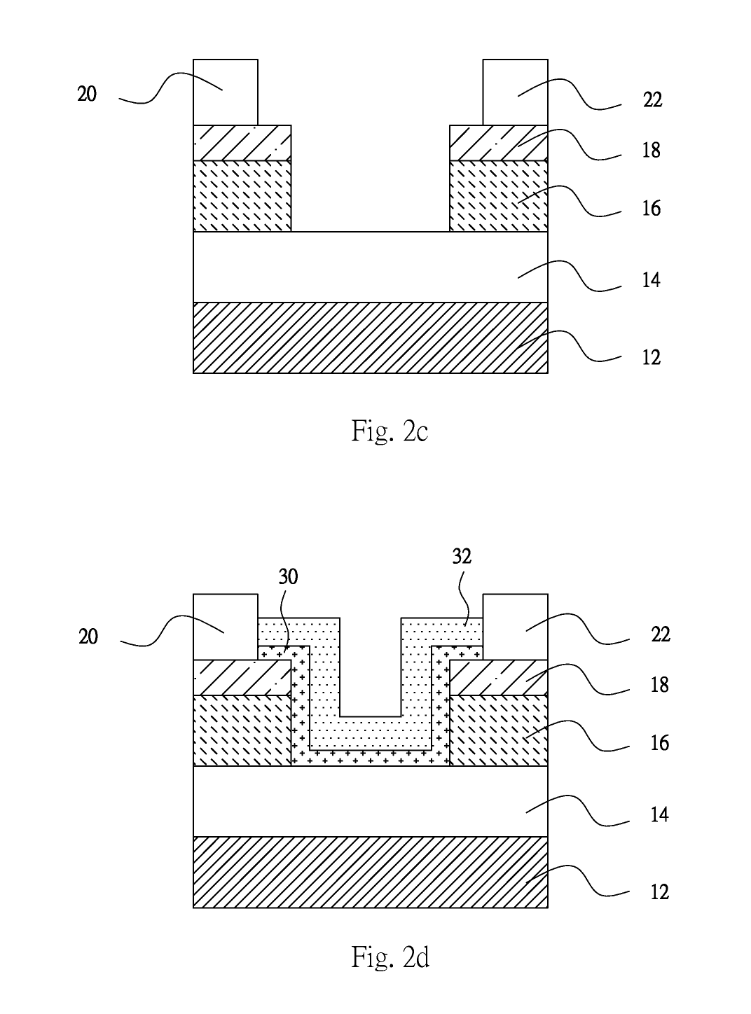

Refer to FIGS. 2a-2d, and refer to FIG. 1 again. FIGS. 2a-2d are sectional views schematically showing the steps of a method for manufacturing a high electron mobility transistor according to one embodiment of the present invention. As shown in FIG. 2a, sequentially epitaxially grow a channel layer 14, a donor supply layer 16 and a protection layer 18 on a substrate 12 by a metal-organic chemical vapor deposition (MOCVD) technology. In some embodiments, the channel layer 14 is made of a first group III-V compound, such as gallium nitride, gallium arsenide, or indium phosphide. In some embodiments, the donor supply layer 16 is made of a second group III-V compound different from the first group III-V compound, such as gallium aluminum nitride, gallium aluminum arsenide, or indium aluminum phosphide.

Next, as shown in FIG. 2b, undertake an ohmic contact fabrication process. The operation principle of an ohmic contact is as follows: the work function of the metal must be smaller than the work function of the semiconductor. Thereby, the electrons can easily cross the energy gap from the metal to the semiconductor and from the semiconductor to the metal. In other words, the current can flow bidirectionally between the metal and the semiconductor. Therefore, an ohmic contact enables an element to have higher current density, higher transconductance, and less energy wasted in generating heat. Traditionally, an ohmic contact is mainly made of a Ti/Al alloy. Titanium can reacts with gallium aluminum nitride to form titanium nitride, whereby to acquire the nitrogen n-doping effect on the surface. After high-temperature annealing, the Ti/Al alloy will form a superior ohmic contact. In some embodiments, the Ti/Al alloy is formed on the surface of the protection layer 18 with an electron beam evaporation process and a lift-off process. Next, the semi-product is annealed at a temperature of 800° C. for 60 seconds in a high-temperature fast anneal furnace with a nitrogen atmosphere to form the source structure 20 and drain structure 22 respectively having ohmic contacts.

Next, as shown in FIG. 2c, undertake a mesa isolation process. The mesa isolation process is to define the active area. The 2DEG exists in the interface between the donor supply layer 16 and the channel layer 14. In order to separate the two elements, a dry etching process is used to form a recess having the required depth. In some embodiments, the ICP-RIE (Inductively Coupled Plasma Reactive Ion Etching) process is used to etch off the group III-V compound with physical and chemical reactions in a BCl₃/Cl₂ atmosphere. In other words, a dry-etching process is used to form a recess in the region where the gate is to be formed. It should be noted that the gallium aluminum nitride layer (the donor supply layer 16) is completely etched off so as to guarantee that HEMT 1 has the normally-off characteristic.

Next, as shown in FIG. 2d, undertake a PE-ALD (Plasma Enhanced Atomic Layer Deposition) process. A polycrystalline aluminum nitride layer (the interfacial passivation layer 30) is deposited on the inner surface of the recess of the aluminum nitride layer (the donor supply layer 16) with TMA (trimethylaluminium) and NH3 (hydrogen nitride) as the precursors without violating the vacuum of the chamber (in-situ) to passivate the surface of the elements. It should be noted that the polycrystalline aluminum nitride layer fabricated with the PE-ALD process in the present invention is less likely to crack and has a better electron barrier effect than the monocrystalline aluminum nitride layer fabricated with the MOCVD process in the conventional technology. However, the PE-ALD process is only an exemplification of the present invention. The present invention does not limit that the interfacial passivation layer 30 must be fabricated with the PE-ALD process. The persons skilled in the art can modify or vary the process to decrease the density of cracks in the interface between the dielectric layer 32 and the semiconductor layer to maintain the threshold voltage and improve the reliability of the transistor without departing from the scope of the present invention.

Next, deposit a high permittivity layer (the dielectric layer 32) on the interfacial passivation layer 30 in the identical chamber to further raise the threshold voltage of the transistor to a higher level and guarantee that the transistor would not be turned on abnormally in a high-voltage operation environment. In some embodiments, the dielectric layer 32 is made of aluminum oxide (Al₂O₃).

Then, undertake a Schottky contact fabrication process. The Schottky contact is a key for the operation of the gate. The work function of the metallic material of the Schottky contact must be larger than the work function of the semiconductor and must satisfy the difference of the work functions. The energy barrier height and the current transmission mechanism are the chief considerations in selecting a Schottky contact material. In some embodiments, a Ni/Al alloy is used to fabricate a gate structure 34 on the dielectric layer 32 to achieve better electric performance. Thereby is completed the high electron mobility transistor 1 shown in FIG. 1.

Refer to FIG. 3 a sectional view schematically showing a high electron mobility transistor according to another embodiment of the present invention. This embodiment is different from the abovementioned embodiment in that the high electron mobility transistor 1 further comprises a buffer layer 13 formed on the substrate 12. In this embodiment, the buffer layer 13 includes a composite layer having a total thickness of about 1 μm and consisting of a gallium nitride layer, a gallium aluminum nitride layer and an aluminum nitride layer. The channel layer 14 is a gallium nitride layer having a thickness of about 4 μm. The donor supply layer 16 is an aluminum gallium nitride (Al_{0.23}Ga_{0.77}N) layer having a thickness of about 25 nm, formed on the channel layer 14 and having a recess. The protection layer 18 is a gallium nitride layer having a thickness of about 2 nm and formed on the donor supply layer 16. The source structure 20 and the drain structure 22 are made of a Ti/Al/Ni/Au alloy and respectively have ohmic contacts with the protection layer 18. The interfacial passivation layer 30 is an aluminum nitride layer having a thickness of about 2 nm. The dielectric layer 32 is an aluminum oxide layer having a thickness of about 8 nm. The gate structure 34 is made of a Ni/Au alloy, and the surface thereof has a length of 2 μm and a width of 50 μm.

Refer to FIG. 4 showing the relationship of the drain current and the gate bias and the relationship of the transconductance and the gate bias, wherein the right vertical coordinate axis is for the solid circle curve and the left vertical coordinate axis is for the open circle curve. From FIG. 4, it is observed that the transistor has a threshold voltage of 1.5V, which is obtained in the forward scan and reverse scan of the gate bias between −1V and 5V. It indicates that the transistor is a normally-off gallium nitride transistor. It is observed in FIG. 4 that the transistor has a transconductance of as high as 140 mS/mm. Therefore, the HEMT of the present invention has higher threshold voltage and higher transconductance than the conventional HEMT and is more suitable to operate in a high-voltage environment.

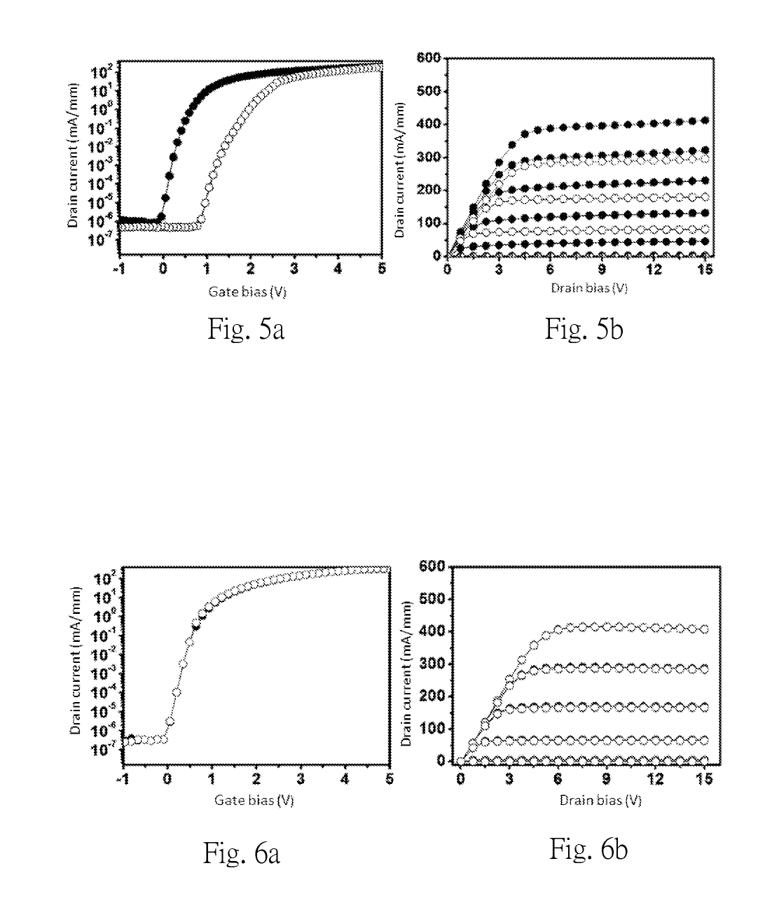

Refer to FIG. 5a, FIG. 5b, FIG. 6a and FIG. 6b for the efficacies and advantages of the present invention. FIG. 5a shows the relationship of the drain current and the gate bias of a control-group transistor whose gate is free of the interfacial passivation layer, wherein the solid circle curve is the relationship of the drain current and the gate bias increasing from 0V to 5V; the open circle curve is the relationship of the drain current and the gate bias decreasing from 5V to 0V. It is observed in FIG. 5a that the threshold voltages of the control-group transistor, which are respectively obtained in the forward scan and reverse scan of the gate bias between 0 and 5V, have a difference of 0.8V. It is observed in FIG. 5b that the relationship of the drain output current and the drain bias of the control-group transistor is unstable in the forward scan and reverse scan of the gate bias. It is observed in FIG. 6a that the threshold voltages of a normally-off HEMT 1 of the present invention, which are respectively obtained in the forward scan and reverse scan of the gate bias, have a difference of only 65 mV. It is observed in FIG. 6b that the relationship of the drain output current and the drain bias of the normally-off HEMT 1 of the present invention is very stable in the forward scan and reverse scan of the gate bias. Therefore, the present invention solves the problem of threshold voltage hysteresis that is likely to occur in the conventional transistor and enables the transistor to provide highly stable output current.

In conclusion, the present invention proposes a high electron mobility transistor featuring a gate recessed structure, a high-permittivity oxide layer and a nitride interfacial passivation layer, whereby to realize a high electron mobility transistor with highly stable threshold voltage and high reliability. The present invention also proposes a method for manufacturing a high electron mobility transistor, which uses a PE-ALD technology to grow a polycrystalline aluminum nitride layer (the interfacial passivation layer) less likely to crack and more efficient to retard electrons than the conventional monocrystalline aluminum nitride fabricated by the MOCVD technology. The high electron mobility transistor of the present invention is in a non-conduction state at zero gate voltage (normally-off), avoiding unnecessary power consumption and having high power efficiency. The interfacial passivation layer of the present invention can reduce the density of cracks in the interface between the semiconductor layer and the gate dielectric layer, maintaining the threshold voltage at high stability and the transistor operation at high reliability. In comparison with the conventional high electron mobility transistor, the high electron mobility transistor of the present invention overcomes threshold voltage hysteresis effectively, operates stably in high-voltage environment, and features high threshold voltage, high transconductance and highly stable drain output current.

The embodiments have been described above to demonstrate the technical thought and characteristics of the present invention to enable the persons skilled in the art to understand, make, and use the present invention. However, these embodiments are only to exemplify the present invention but not to limit the scope of the present invention. Any equivalent modification or variation according to the spirit of the present invention is to be also included within the scope of the present invention.

What is claimed is:

1. A high electron mobility transistor comprising:
a substrate;
a channel layer formed on said substrate and including a first group III-V compound;
a donor supply layer formed on said channel layer, including a second group III-V compound that is different from said first group III-V compound, and having a recess exposing a portion of said channel layer;
a source structure formed on said donor supply layer and having an ohmic contact with said donor supply layer;
a drain structure formed on said donor supply layer and having an ohmic contact with said donor supply layer, wherein said source structure and said drain structure are respectively disposed at opposite sides of said recess;
an interfacial passivation layer formed on an inner surface of said recess;
a dielectric layer formed on said interfacial passivation layer; and
a gate structure formed on said dielectric layer and corresponding to said recess.

2. The high electron mobility transistor according to claim 1, wherein said interfacial passivation layer includes an aluminum nitride layer.

3. The high electron mobility transistor according to claim 1, wherein said interfacial passivation layer includes an aluminum nitride layer and has a thickness of 2-20 nm.

4. The high electron mobility transistor according to claim 1 further comprising:
a protection layer disposed above said donor supply layer and below said source structure and said drain structure.

5. The high electron mobility transistor according to claim 4, wherein said protection layer includes a gallium nitride layer.

6. The high electron mobility transistor according to claim 1 further comprising:
a buffer layer interposed between said substrate and said channel layer.

7. The high electron mobility transistor according to claim 6, wherein said buffer layer includes at least one of an aluminum nitride layer, a gallium aluminum nitride layer, and a gallium nitride layer.

8. The high electron mobility transistor according to claim 1, wherein said dielectric layer includes a high-permittivity material.

9. The high electron mobility transistor according to claim 1, wherein said dielectric layer includes silicon dioxide, nitrogen oxide, or aluminum oxide.

10. The high electron mobility transistor according to claim 1, wherein said first group III-V compound includes gallium nitride, gallium arsenide, or indium phosphide.

11. The high electron mobility transistor according to claim 1, wherein said second group III-V compound includes gallium aluminum nitride, gallium aluminum arsenide, or indium aluminum phosphide.

12. A method for manufacturing a high electron mobility transistor comprising:
forming a channel layer including a first group III-V compound on a substrate;
forming a donor supply layer including a second group III-V compound on said channel layer;
forming a source structure and a drain structure, which are separated from each other and respectively have ohmic contacts with said donor supply layer, on said donor supply layer;
forming a recess disposed between said source structure and said drain structure and exposing a portion of said channel layer in said donor supply layer;
forming an interfacial passivation layer on an inner surface of said recess;
forming a dielectric layer on said interfacial passivation layer; and
forming a gate structure on said dielectric layer and corresponding to said recess.

13. The method for manufacturing a high electron mobility transistor according to claim 12, wherein said interfacial passivation layer is formed on said inner surface of said recess in a plasma enhanced atom layer deposition technology.

14. The method for manufacturing a high electron mobility transistor according to claim 12, wherein said interfacial passivation layer includes an aluminum nitride layer.

15. The method for manufacturing a high electron mobility transistor according to claim 12, wherein said interfacial passivation layer includes an aluminum nitride layer and has a thickness of 2-20 nm.

16. The method for manufacturing a high electron mobility transistor according to claim 12 further comprising:
forming a protection layer above said donor supply layer and below said source structure and said drain structure.

17. The method for manufacturing a high electron mobility transistor according to claim 16, wherein said protection layer includes a gallium nitride layer.

18. The method for manufacturing a high electron mobility transistor according to claim 12 further comprising:
forming a buffer layer between said substrate and said channel layer.

19. The method for manufacturing a high electron mobility transistor according to claim 18, wherein said buffer layer includes at least one of an aluminum nitride layer, a gallium aluminum nitride layer, and a gallium nitride layer.

20. The method for manufacturing a high electron mobility transistor according to claim 12, wherein said dielectric layer includes a high-permittivity material.

21. The method for manufacturing a high electron mobility transistor according to claim 12, wherein said dielectric layer includes silicon dioxide, nitrogen oxide, or aluminum oxide.

22. The method for manufacturing a high electron mobility transistor according to claim 12, wherein said first group III-V compound includes gallium nitride, gallium arsenide, or indium phosphide.

23. The method for manufacturing a high electron mobility transistor according to claim 12, wherein said second group III-V compound includes gallium aluminum nitride, gallium aluminum arsenide, or indium aluminum phosphide.
